(19) United States
(12) Patent Application Publication
(10) Pub. No.: US 2008/0122491 A1
(43) Pub. Date: May 29, 2008

(54) FREQUENCY COMPARATOR, FREQUENCY SYNTHESIZER, AND RELATED METHODS THEREOF

(76) Inventor: Chien-Wei Kuan, Tai-Tung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/566,233

(22) Filed: Dec. 3, 2006

Related U.S. Application Data
(60) Provisional application No. 60/826,220, filed on Sep. 20, 2006.

(51) Int. Cl. G01R 23/02; H03B 28/00; H03D 13/00

(52) U.S. Cl. 327/43; 327/101; 327/39

(57) ABSTRACT

The present invention discloses a frequency comparator for comparing frequencies of a first signal and a second signal. The frequency comparator includes: a frequency detecting circuit for generating a reference signal according to the first signal and an input voltage; a frequency generator for generating the second signal according to the input voltage; a charge pump circuit for enabling a charging current according to either the reference signal or the second signal to increase an voltage level, and for enabling a discharging current according to the other signal to decrease the voltage level; and a decision logic coupled to the charge pump circuit for indicating a frequency relation between frequencies of the first signal and the second signal according to the voltage level.

### CROSS REFERENCE TO RELATED APPLICATIONS

This application claims the benefit of U.S. Provisional Application No. 60/826,220, which was filed on Sep. 20, 2006 and is included herein by reference.

### BACKGROUND OF THE INVENTION

1. Field of the Invention

The present invention relates to clock signal processing, and more particularly, to an analog frequency comparator referring to a voltage for setting an internal frequency and comparing an external frequency and the internal frequency, a frequency synthesizer adopting the concept applied to the analog frequency comparator for synthesizing a clock signal, and related methods thereof.

2. Description of the Prior Art

In the application field of integrated circuits (IC), an external pin is always required to receive an external clock having an additional frequency different from that of an internally generated clock. Therefore, the integrated circuit has to be able to determine the speed of two frequencies and to determine which clock signal having a desired frequency is going to be selected. In the prior art, the combination of a phase-frequency detector (PFD), a counter, and a plurality of digital logics can be utilized to select a frequency for the internal operation. However, the PFD, the counter, and the plurality of digital logics occupy a lot of chip area of the IC, resulting in a high production cost.

Please refer to FIG. 1. FIG. 1 is a diagram illustrating a prior art frequency comparator 10. The conventional frequency comparator 10 comprises a frequency detecting circuit 11, a first counter circuit 12, a second counter circuit 13, and a decision logic 14. When a first clock signal IN1 and a second clock signal IN2 are concurrently inputted into the frequency detecting circuit 11, a first reset signal RST1 and a second reset signal RST2 corresponding to the first clock signal IN1 and the second clock signal IN2 respectively are transmitted to the first counter circuit 12 and the second counter circuit 13. The first reset signal RST1 and the second reset signal RST2 reset the first counter circuit 12 and the second counter circuit 13 respectively to start counting clock cycles of the first clock signal IN1 and the second clock signal IN2. If the frequency of the first clock signal IN1 is higher than that of the second clock signal IN2, an overflow signal OF1 will first be outputted and then the other overflow signal OF2 will be outputted. The overflow signals OF1 and OF2 are inputted to the decision logic 14, and the decision logic 14 refers to the overflow signals OF1 and OF2 to output a status signal indicating the frequency relationship between the first clock signal IN1 and the second clock signal IN2. Referring to U.S. Pat. No. 6,834,093 B1, another prior art frequency comparator is disclosed. Further description is not detailed here for simplicity.

Moreover, after the IC receives an external frequency, the IC may need to synthesize an internal clock having a frequency equal to any multiple of the external frequency, or the IC may need to use the external frequency to provide a plurality of clock signals having different phases. Therefore, a frequency synthesizer or a frequency multiplier is needed.

### SUMMARY OF THE INVENTION

Therefore, one of the objectives of the present invention is to provide an analog frequency comparator referring to a voltage for setting an internal frequency and comparing an external frequency and the internal frequency, a frequency synthesizer adopting the concept applied to the analog frequency comparator for synthesizing a clock signal, and related methods thereof.

According to an embodiment of the present invention, a frequency comparator is provided for comparing frequencies of a first signal and a second signal. The frequency comparator comprises a frequency detecting circuit, a frequency generator, a charge pump circuit, and a decision logic. The frequency detecting circuit generates a reference signal according to the first signal and an input voltage; the frequency generator generates the second signal according to the input voltage; the charge pump circuit is coupled to the frequency detecting circuit and the frequency generator for enabling a charging current according to either the reference signal or the second signal to increase a voltage level, and for enabling a discharging current according to the other signal in order to decrease the voltage level; and the decision logic is coupled to the charge pump circuit for indicating a frequency relation between frequencies of the first signal and the second signal according to the voltage level.

According to an embodiment of the present invention, a frequency synthesizer is provided for generating a second signal according to a first signal. The frequency synthesizer comprises a frequency detecting circuit, a frequency generator, a charge pump circuit, and an adjusting circuit. The frequency detecting circuit generates a reference signal according to the first signal and a first input voltage; the frequency generator generates the second signal according to a second input voltage; the charge pump circuit is coupled to the frequency detecting circuit and the frequency generator for enabling a charging current according to either the reference signal or the second signal in order to increase a voltage level, and for enabling a discharging current according to the other signal for decreasing the voltage level; and the adjusting circuit is coupled to the charge pump circuit, the frequency detecting circuit, and the frequency generator for adjusting the frequency detecting circuit and the frequency generator according to the voltage level to thereby tune frequencies of the reference signal and the second signal.

According to an embodiment of the present invention, a frequency comparing method is provided for comparing frequencies of a first signal and a second signal. The frequency comparing method comprises the steps of: generating a reference signal according to the first signal and an input voltage; generating the second signal according to the input voltage; enabling a charging current according to either the reference signal or the second signal to increase an voltage level, and enabling a discharging current according to the other signal to decrease the voltage level; and indicating a frequency relation between frequencies of the first signal and the second signal according to the voltage level.

According to an embodiment of the present invention, a frequency synthesizing method is provided for generating a second signal according to a first signal. The frequency synthesizing method comprises the steps of: generating a reference signal according to the first signal and a first input voltage; generating the second signal according to a second input voltage; enabling a charging current according to either the reference signal or the second signal to increase an voltage level, and for enabling a discharging current according to the other signal to decrease the voltage level; and adjusting the frequency detecting circuit and the frequency generator according to the voltage level to thereby tune frequencies of the reference signal and the second signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a prior art frequency comparator.

FIG. 2 is a diagram of a frequency comparator according to an embodiment of the present invention.

FIG. 3 is a diagram of an embodiment of a bias generator shown in FIG. 1.

FIG. 4 is a diagram of an embodiment of a single-pulse generating circuit shown in FIG. 2.

FIG. 5 is a timing diagram of a delay signal, a first signal, a one pulse signal, and a first saw-tooth signal shown in FIG. 4 and FIG. 2.

FIG. 6 is a diagram of an embodiment of a first saw-tooth waveform generator shown in FIG. 2.

FIG. 7 is a diagram of an embodiment of a second saw-tooth waveform generator shown in FIG. 2.

FIG. 8 is a diagram of a second signal, a second saw-tooth signal, and an input voltage shown in FIG. 7 and FIG. 2.

FIG. 9 is a diagram of an embodiment of a charge pump circuit shown in FIG. 2.

FIG. 10 is a timing diagram of a reference signal, the first saw-tooth signal, and the input voltage shown in FIG. 6 and FIG. 2.

FIG. 11 is a diagram of a frequency synthesizer according to an embodiment of the present invention.

FIG. 12 is a timing diagram of a first input voltage, a first saw-tooth signal, and a second saw-tooth signal shown in FIG. 11.

FIG. 13 is a flow chart of a frequency comparing method according to an embodiment of the present invention.

FIG. 14 is a flow chart of a frequency synthesizing method according to an embodiment of the present invention.

### DETAILED DESCRIPTION

Certain terms are used throughout the following description and claims to refer to particular system components. As one skilled in the art will appreciate, consumer electronic equipment manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

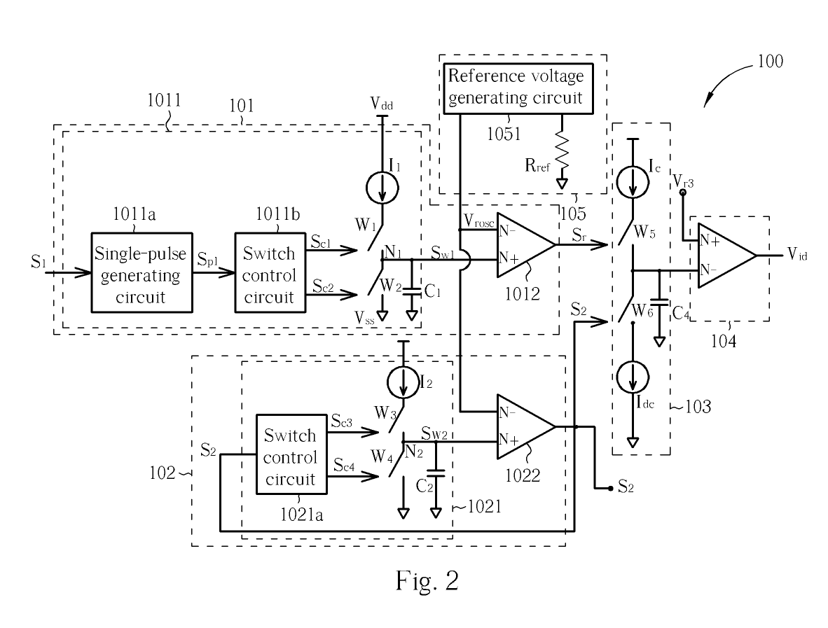

Please refer to FIG. 2. FIG. 2 is a diagram illustrating a frequency comparator 100 according to an embodiment of the present invention. The frequency comparator 100 is utilized for comparing the frequency of a first signal S₁ (i.e. an external clock signal) and a second signal S₂ (i.e. an internal clock). The frequency comparator 100 comprises a frequency detecting circuit 101, a frequency generator 102, a charge pump circuit 103, a decision logic 104, and a bias generator 105. The frequency detecting circuit 101 generates a reference signal Sᵣ according to the first signal S₁ and an input voltage V_{rosc}. The frequency generator 102 generates the second signal S₂ according to the input voltage V_{rosc}. The charge pump circuit 103 is coupled to the frequency detecting circuit 101 and the frequency generator 102 for enabling a charging current I_{c} according to either the reference signal Sᵣ or the second signal S₂ to increase an voltage level Vₒₛₑₜ, and for enabling a discharging current I_{dc} according to the other of the reference signal Sᵣ and the second signal S₂ to decrease the voltage level Vₒₛₑₜ. The decision logic 104 is coupled to the charge pump circuit 103 for indicating a frequency relation between frequencies of the first signal S₁ and the second signal S₂ according to the voltage level Vₒₛₑₜ outputted by the charge pump circuit 103. Additionally, the bias generator 105 is coupled to the frequency detecting circuit 101 and the frequency generator 102 for generating the input voltage V_{rosc}.

It should be noted that, in this embodiment, the charging operation is controlled by the reference signal Sᵣ, and the discharging operation is controlled by the second signal S₂. However, this is not meant to be a limitation of the present invention. For example, in an alternative design, the discharging operation is controlled by the reference signal Sᵣ, and the charging operation is controlled by the second signal S₂. The frequency relation between frequencies of the first signal S₁ and the second signal S₂ can be identified according to the voltage level Vₒₛₑₜ.

The detailed operations of the circuit components within the frequency comparator 100 are given as below. According to the embodiment in FIG. 2 of the present invention, the frequency detecting circuit 101 comprises a first saw-tooth waveform generator 1011 and a first comparator 1012, where the first saw-tooth waveform generator 1011 is coupled to the first signal S₁ for converting the first signal S₁ into a first saw-tooth signal S_{w1}, and the first comparator 1012 is coupled to the first saw-tooth signal S_{w1} and the input voltage V_{rosc} for comparing the first saw-tooth signal S_{w1} and the input voltage V_{rosc} to generate the reference signal Sᵣ. The first saw-tooth waveform generator 1011 comprises a single-pulse generating circuit 1011a, a first capacitor C₁, a first current source I₁, a first switch W₁, a second switch W₂, and a switch control circuit 1011b. As shown in FIG. 2, the single-pulse generating circuit 1011a is coupled to the first signal S₁ for generating one pulse signal (i.e. Sₚ₁) in each cycle of the first signal S₁. The first capacitor C₁ is coupled between an output node N₁ of the first saw-tooth waveform generator 1011 and a first reference voltage Vₛₛ (i.e. a ground voltage). The first current source I₁ is coupled to a second reference voltage V_{dd} (i.e. a supply voltage). The first switch W₁ is coupled between the first current source I₁ and the output node N₁ of the first saw-tooth waveform generator 1011 for selectively coupling the first current source I₁ to the first capacitor C₁ according to a first switch control signal S_{c1}. The second switch W₂ is coupled between the output node N₁ of the first saw-tooth waveform generator 1011 and the first reference voltage Vₛₛ, for selectively coupling the first capacitor C₁ to the first reference voltage Vₛₛ according to a second switch control signal S_{c2}. The switch control circuit 1011b is coupled to the single-pulse generating circuit 1011a, the first switch W₁, and the second switch W₂, for generating the first switch control signal Sci and the second switch control signal S_{c2} according to an output signal Sₚ₁ of the first single-pulse generating circuit 1011a.

Please refer to FIG. 2 again. The frequency generator 102 comprises a second saw-tooth waveform generator 1021, and a second comparator 1022. The second saw-tooth waveform generator 1021 is coupled to the second signal S₂ for converting the second signal S₂ into a second saw-tooth signal S_{w2}; and the second comparator 1022 is coupled to the second saw-tooth signal S_{w2} and the input voltage V_{rosc}, for comparing the second saw-tooth signal S_{w2} and the input voltage V_{rosc} to generate the second signal S₂. Furthermore, the second saw-tooth waveform generator 1021 comprises a second capacitor C₂, a second current source I₂, a third switch W₃, a fourth switch W₄, and a switch control circuit 1021a. The second capacitor C₂ is coupled between an output node N₂ of the second saw-tooth waveform generator 1021 and the first reference voltage Vₛₛ. The second current source I₂ is coupled to the second reference voltage V_{dd}. The third switch W₃ is coupled between the second current source I₂ and the output node N₂ of the second saw-tooth waveform generator 1021 for selectively coupling the second current source I₂ to the second capacitor C₂ according to a third switch control signal S_{c3}. The fourth switch W₄ is coupled between the output node N₂ of the second saw-tooth waveform generator 1021 and the first reference voltage Vₛₛ for selectively coupling the capacitor C₂ to the first reference voltage Vₛₛ according to a fourth switch control signal S_{c4}. The switch control circuit 1021a is coupled to the second signal S₂, the third switch W₃, and the fourth switch W₄ for generating the third switch control signal S_{c3} and the fourth switch control signal S_{c4} according to the second signal S₂ outputted from the output node N₂ of the second saw-tooth waveform generator 1021.

Furthermore, the decision logic 104 is coupled to the voltage level Vₒₛₑₜ and a third reference voltage Vᵣ₃ to output an indication signal V_{id} indicating the frequency relation between frequencies of the first signal S₁ and the second signal S₂. In this embodiment, the bias generator 105 comprises a resistor R_{ref} and a reference voltage generating circuit 1051, where the reference voltage generating circuit 1051 is coupled to the resistor R_{ref} for setting the input voltage V_{rosc} according to a resistance of the implemented resistor R_{ref}. Please note that the reference voltage generating circuit 1051, the frequency detecting circuit 101, the frequency generator 102, the charge pump circuit 103, and the decision logic 104 are all integrated in a chip, while the resistor R_{ref} is external to the chip. In other words, the resistance of the external resistor R can be easily adjusted. In operation, when the resistor R_{ref} is coupled externally to the reference voltage generating circuit 1051, the input voltage V_{rosc} is set, in which the input voltage V_{rosc} decides the frequency f₂ of the second signal S₂ generated by frequency generator 102. Setting the input voltage V_{rosc} is detailed as below.

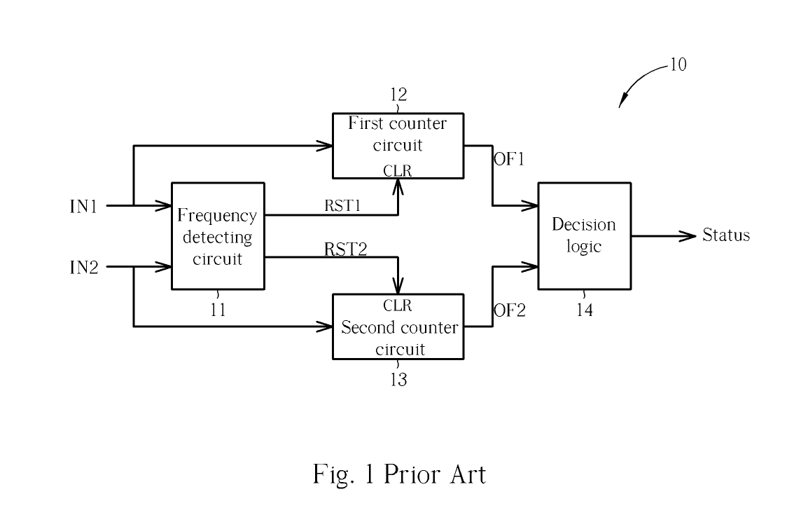

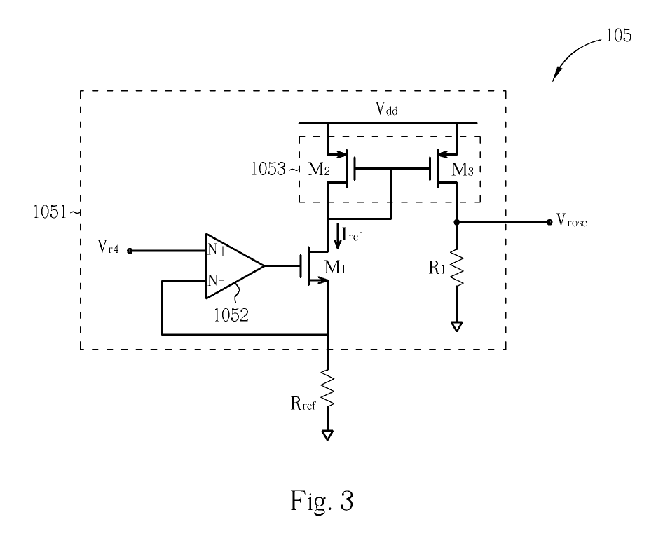

Please refer to FIG. 3. FIG. 3 is a diagram illustrating an embodiment of the bias generator 105 in FIG. 1. Through a closed-loop-connected error amplifier 1052 and a pass transistor M₁, a fourth reference voltage Vᵣ₄ is coupled to the resistor R_{ref} to generate a reference current I_{ref}, wherein I_{ref}=Vᵣ₄/R_{ref}. The reference current I_{ref} is then mirrored by a current mirror circuit 1053 to generate a mirror current Iₘᵢᵣᵣₒᵣ. As known to those skilled in this art, the current mirror ratio Nₘᵢᵣᵣₒᵣ of the current mirror circuit 1053 can be directly set by the PMOS transistors M₂ and M₃ or using other available means. Accordingly, the input voltage V_{rosc} can be obtained by flowing the mirror current Iₘᵢᵣᵣₒᵣ through a resistor R₁. Therefore, V_{rosc}=Nₘᵢᵣᵣₒᵣ*(R₁/R_{ref}) Vᵣ₄. Please note that the circuit configuration shown in FIG. 3 is for illustrative purposes only, and is not meant to be taken as a limitation of the present invention.

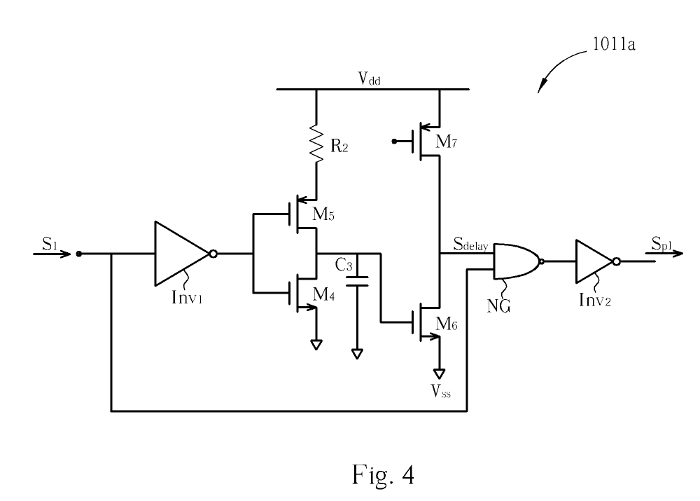

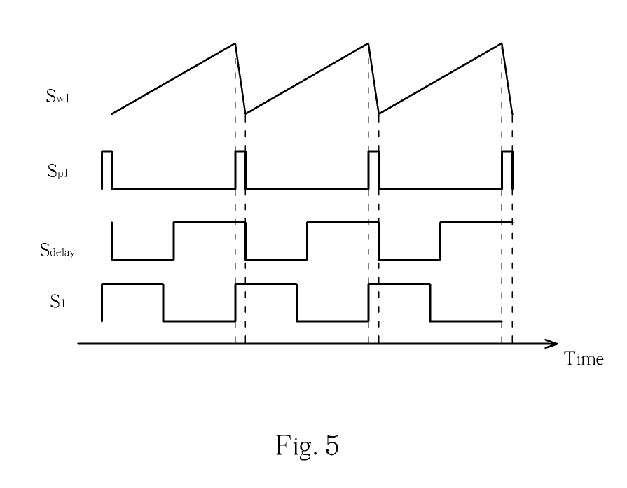

Regarding the single-pulse generating circuit 1011a, when the first signal S₁ is inputted, the single-pulse generating circuit 1011a generates the one pulse signal Sₚ₁ in each cycle of the first signal S₁ for the following circuit component in order to avoid the duty cycle variation problem of the first signal S₁. Please refer to FIG. 4. FIG. 4 is a diagram illustrating an embodiment of the single-pulse generating circuit 1011a in FIG. 2. The single-pulse generating circuit 1011a comprises a plurality of inverters Inv₁, Inv₂, a plurality of transistors M₄, M₅, M₆, M₇, a third capacitor C₃, a resistor R₂, and a NAND gate NG. The first signal S₁ is first delayed by a delay unit formed by the inverter Inv₁, the transistors M₄, M₅, M₆, M₇, the third capacitor C₃, and the resistor R₂ in FIG. 4 for generating a delay signal S_{delay}, and then inputted to the NAND gate NG. Next, the NAND gate NG compares the delay signal S_{delay} and the first signal S₁ to output the one pulse signal Sₚ₁ as shown in FIG. 5. FIG. 5 is a timing diagram of the delay signal S_{delay}, the first signal S₁, the one pulse signal Sₚ₁, and the first saw-tooth signal S_{w1} shown in FIG. 4 and FIG. 2. Because the operation of the delay unit can be easily understood by those skilled in this art, the detailed description is omitted here for brevity. Please note that the circuit configuration shown in FIG. 4 is for illustrative purposes only, and is not meant to be a limitation of the present invention. In other words, any single-pulse generating circuit capable of providing the desired one pulse signal Sₚ₁ can be utilized in the present invention.

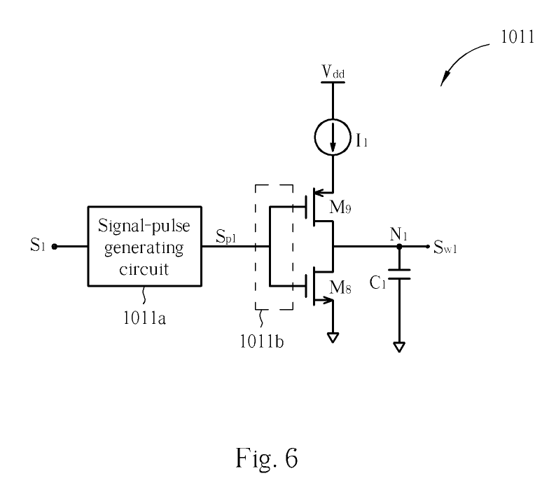

Regarding the switch control circuit 1011b, it receives and converts the one pulse signal Sₚ₁ into the first switch control signal S_{c1} and the second switch control signal S_{c2}. Please refer to FIG. 5 in conjunction with FIG. 6. FIG. 6 is a diagram illustrating an embodiment of the first saw-tooth waveform generator 1011 in FIG. 2. In this simplified embodiment, the switch control circuit 1011b serves as a transmission path only without performing any signal processing upon the incoming one pulse signal Sₚ₁, and the first switch W₁ and the second switch W₂ can be implemented using transistors M₈ and M₉. Please note that this is not meant to be a limitation of the present invention. The low level of the one pulse signal Sₚ₁ turns on the transistor M₉ and turns off the transistor M₈ to thereby charge the output node N₁ by the first current source I₁; and the impulse of the one pulse signal Sₚ₁ turns off the transistor M₉ and turns on the transistor M₈ to thereby discharge the output node N₁ to the ground voltage quickly. Accordingly, the first saw-tooth signal S_{w1} shown in FIG. 5 can be obtained.

Regarding the first comparator 1012 shown in FIG. 2, it is configured to compare the first saw-tooth signal S_{w1} and the input voltage V_{rosc} to generate the reference signal Sᵣ. In this embodiment, the input voltage V_{rosc} is coupled to the inverting terminal (i.e. N−) of the first comparator 1012, and the first saw-tooth signal S_{w1} is coupled to the non-inverting terminal (i.e. N+) of the first comparator 1012. In addition, if the highest voltage of the first saw-tooth signal S_{w1} that corresponds to the frequency of the first signal S₁ is lower than the input voltage V_{rosc}, the reference signal Sᵣ therefore always remains at a low voltage level. However, if the highest voltage of the first saw-tooth signal S_{w1} that corresponds to the frequency of the first signal S₁ exceeds the input voltage V_{rosc}, the reference signal Sᵣ always remains at a low voltage level. However, if the highest voltage of the first saw-tooth signal S_{w1} that corresponds to the frequency of the first signal S₁ exceeds the input voltage V_{rosc}, the reference signal Sᵣ is equivalent to a one-pulse signal having a pulse in each cycle of the first signal S₁.

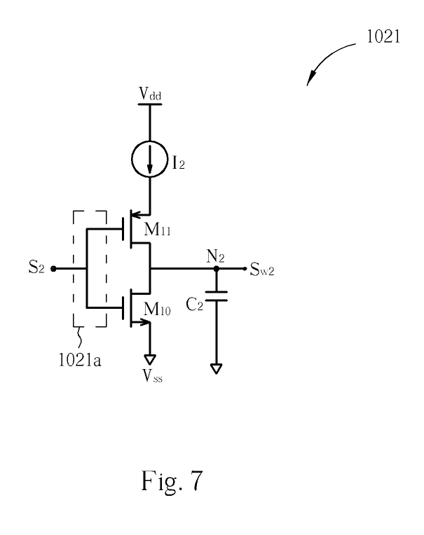

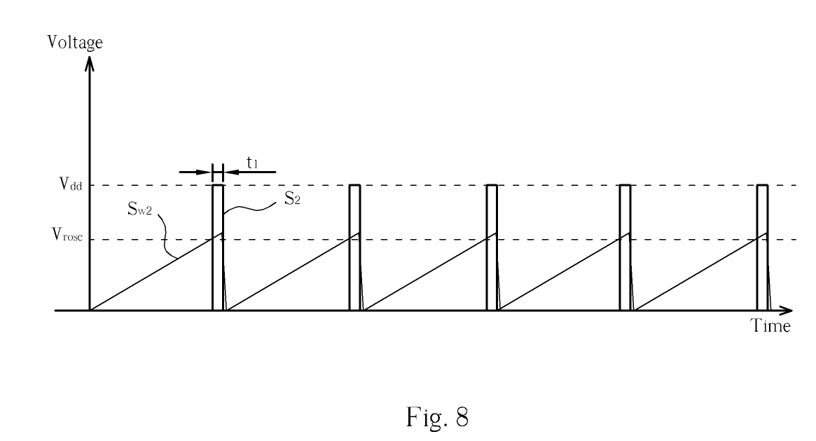

Referring to FIG. 2 again, because the second signal S₂ of the frequency generator 102 is required to be fed back to the switch control circuit 1021a for clock generation, a feedback loop is formed. When the input voltage V_{rosc} is set, the negative feedback characteristic of the frequency generator 102 will induce the second signal S₂. In order to describe the operation of the frequency generator 102 more clearly, the second signal S₂ is assumed to be low voltage level initially. Please refer to FIG. 7. FIG. 7 is a diagram illustrating an embodiment of the second saw-tooth waveform generator 1021 in FIG. 2. In this simplified embodiment, the switch control circuit 1011a serves as a transmission path only without performing any signal processing upon the incoming second signal S₂, and the third switch W₃ and the fourth switch W₄ are implemented using transistors M₁₁, M₁₀. Therefore, the second signal S₂ turns on the transistor M₁₁, and turns off the transistor M₁₀ to charge the second capacitor C₂ at the output node N₂ through the second current source I₂. Please note that, in order to obtain the same ramping (i.e. charging slope) of the first saw-tooth signal S_{w1} when generating the second saw-tooth signal S_{w2}, the second current source I₂, the transistor M₁₀, the transistor M₁₁, and the second capacitor C₂ should be the same as the first current source I₁, the transistor M₈, the transistor M₉, and the first capacitor C₁ of the first saw-tooth waveform generator 1011 respectively. When the second saw-tooth signal S_{w2} increases to reach the input voltage V_{rosc}, the second comparator 1022 turns the voltage level of the second signal S₂ into the high voltage level as shown in FIG. 8. FIG. 8 is a diagram of the second signal S₂, the second saw-tooth signal S_{w2}, and the input voltage V_{rosc} shown in FIG. 7 and FIG. 2. Accordingly, the high voltage level of the second signal S₂ is fed back to the gate terminals of the transistors M₁₀ and M₁₁ to turn off the transistor M₁₁ and turn on the transistor M₁₀. Then the second current I₂ starts charging the second capacitor C₂ to increase the voltage level of the second signal S₂ again. Therefore, the second signal S₂ is generated. Please note that the frequency of the second signal S₂ is dependent on the input voltage V_{rosc}, the second capacitor C₂, and the second current I₂. Furthermore, the time t₁ of the pulse of the second signal S₂ approximates to the feedback time from the second signal S₂ to the second saw-tooth signal S_{w2}. In this embodiment, the resistor R_{ref} is utilized to set the input voltage V_{rosc}; however, another embodiment of the present invention can also change the capacitor C₂ or the second current I₂ to alter the frequency of the second signal S₂. These modifications all fall within the scope of the present invention.

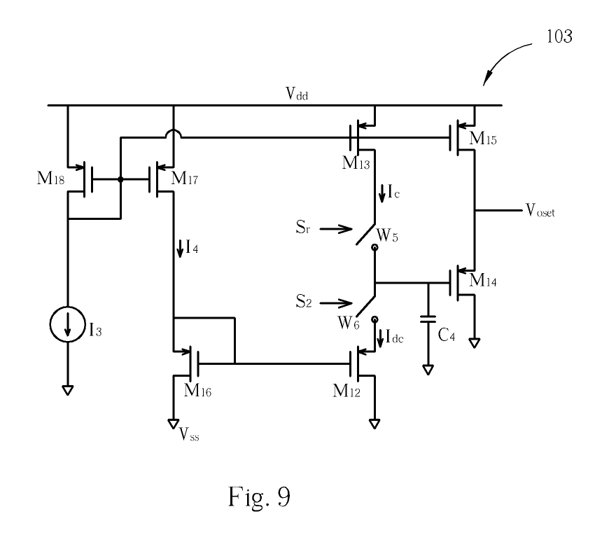

In a case where the frequency of the first signal S₁ is higher than that of the second signal S₂, the highest voltage of the first saw-tooth signal S_{w1} that corresponds to the frequency of the first signal S₁ is less than the input voltage V_{rosc} set through the bias circuit 105, and the reference signal Sᵣ remains at a low voltage level according to the above-mentioned frequency detecting circuit 101; in other words, the charging current I_{c} of the charge pump circuit 103 will not charge a fourth capacitor C₄ in the charge pump circuit 103. Please refer to FIG. 9. FIG. 9 is a diagram illustrating an embodiment of the charge pump circuit 103 shown in FIG. 2. The charge pump circuit 103 comprises a plurality of transistors M₁₂, . . . , M₁₈, a fifth switch W₅, a sixth switch W₆, and the fourth capacitor C₄; wherein the transistors M₁₃ and M₁₈ form a current mirror for mirroring a third current I₃ into the charging current I_{c}, the transistors M₁₇ and M₁₈ form another current mirror for mirroring the third current I₃ into a fourth current I₄; and the transistors M₁₆ and M₁₂ form yet another current mirror for mirroring the fourth current I₄ into the discharging current I_{dc}. Please note that, in this embodiment, the charging current I_{c} should be the same as the discharging current I_{dc}, and it is well known for those skilled in this art to set the aspect ratio of the transistors to obtain the same mirror currents, therefore a detailed description is omitted here for the sake of brevity. Accordingly, the voltage level Vₒₛₑₜ will decrease gradually due to the high voltage period t₁ shown in FIG. 8 until it is lower than the third reference voltage Vᵣ₃ of the decision logic 104. Please note that, in this embodiment, the decision logic 104 is implemented by a comparator, where the voltage level Vₒₛₑₜ is coupled to the inverting terminal (i.e. N−) of the comparator and the third reference voltage Vᵣ₃ is coupled to the non-inverting terminal (i.e. N+) of the comparator as shown in FIG. 2. Then, the output (i.e. the indication signal V_{id}) of the decision logic 104 changes to the high voltage level. Therefore, when the indication signal V_{id} of the decision logic 104 is at the high voltage level, this indicates that the frequency of the first signal S₁ is faster than that of the second signal S₂.

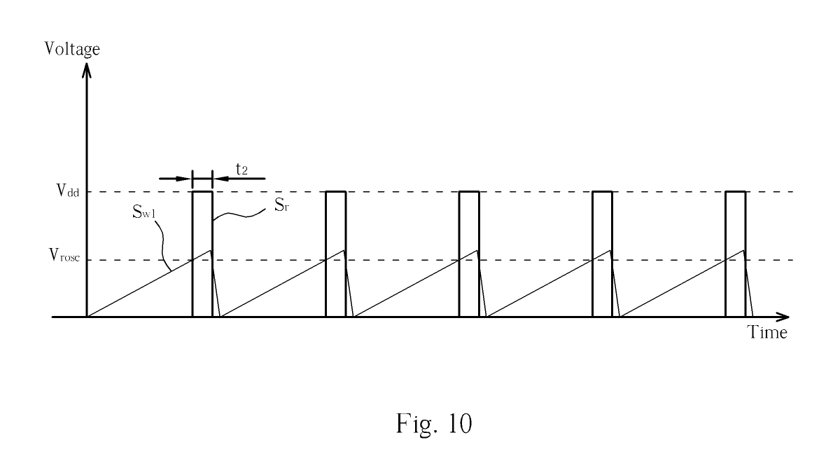

However, in another case where the frequency of the first signal S₁ is lower than that of the second signal S₂, the highest voltage of the first saw-tooth signal S_{w1} that corresponds to the frequency of the first signal S₁ exceeds the input voltage V_{rosc} set through the bias circuit 105, and the reference signal Sᵣ is equivalent to a one pulse signal having a pulse in each cycle of the first signal S₁ according to the aforementioned frequency detecting circuit 101. Please refer to FIG. 8 in conjunction with FIG. 10. FIG. 10 is a timing diagram of the reference signal Sᵣ, the first saw-tooth signal S_{w1}, and the input voltage V_{rosc} shown in FIG. 6 and FIG. 2. Please note that the high voltage period t₂ of the pulse shown in FIG. 10 is dependent on the frequency of the first signal S₁, and the high voltage period t₁ of the pulse shown in FIG. 8 is dependent on the loop response, where the high voltage period t₂ is not less than the high voltage period t₁. As a result, the voltage level Vₒₛₑₜ will increase gradually to reach the third reference voltage Vᵣ₃. Then, the indication signal V_{id} of the decision logic 104 changes to the low voltage level, indicating that the frequency of the first signal S₁ is slower than the second signal S₂.

When the frequencies of the first signal S₁ and the second signal S₂ are determined by the frequency comparator 100 in FIG. 2, the indication signal V_{id} of the decision logic 104 can be utilized for selecting the faster or slower signal between the first signal S₁ and the second signal S₂ (i.e. to become a frequency selector), depending upon the design requirements. Please note that the frequency selector capable of selecting one clock signal out of a plurality of candidate clock signals (e.g., the first signal S₁ and the second signal S₂) according to a selection signal (e.g., the indication signal V_{id}) is well-known to those skilled in this art, and further description is omitted here for the sake of brevity.

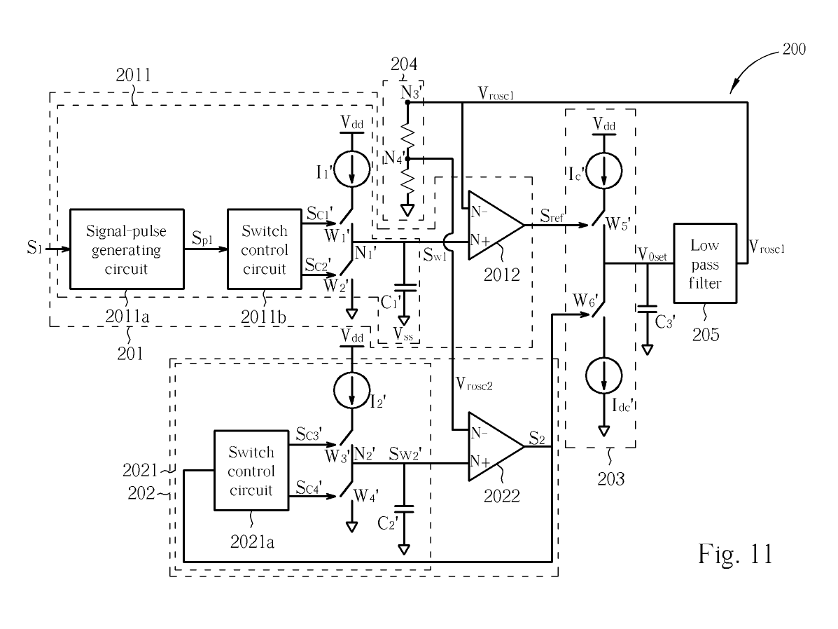

Please refer to FIG. 11. FIG. 11 is a diagram illustrating a frequency synthesizer 200 according to an embodiment of the present invention. The frequency synthesizer 200 generates a second signal S₂ according to a first signal S₁. The frequency synthesizer 200 comprises a frequency detecting circuit 201, a frequency generator 202, a charge pump circuit 203, an adjusting circuit 204, and a low-pass filter 205. The frequency detecting circuit 201 generates a reference signal S_{ref} according to the first signal S₁ and a first input voltage V_{rosc1}. The frequency generator 202 generates the second signal S₂ according to a second input voltage V_{rosc2}. The charge pump circuit 203 is coupled to the frequency detecting circuit 201 and the frequency generator 202 for enabling a charging current I_{c}′ according to either the reference signal S_{ref} and the second signal S₂ to increase an voltage level Vₒₛₑₜ, and for enabling a discharging current I_{dc}′ according to the other of the reference signal S_{ref} and the second signal S₂ to decrease the voltage level Vₒₛₑₜ. In this embodiment, the charging operation is controlled by the reference signal S_{ref}, and the discharging operation is controlled by the second signal S₂. However, this is not meant to be a limitation of the present invention. The adjusting circuit 204 is coupled to the charge pump circuit 203, the frequency detecting circuit 201, and the frequency generator 202, for adjusting the frequency detecting circuit 201 and the frequency generator 202 according to the voltage level Vₒₛₑₜ to thereby tune frequencies of the reference signal V_{ref} and the second signal S2. The low-pass filter 205 is coupled between the charge pump circuit 203 and the adjusting circuit 204 for low-pass filtering the voltage level Vₒₛₑₜ outputted to the adjusting circuit 204 to generate the first input voltage V_{rosc1}. In this embodiment, the low-pass filter 205 is used for extracting a DC level of the voltage level Vₒₛₑₜ to serve as the first input voltage V_{rosc1} fed back to the adjusting circuit 204.

According to the embodiment in FIG. 11 of the present invention, the frequency detecting circuit 201 comprises a first saw-tooth waveform generator 2011 and a first comparator 2012. The first saw-tooth waveform generator 2011 coupled to the first signal S₁ converts the first signal S₁ into a first saw-tooth signal S_{w1}′; and the first comparator 2012 is coupled to the first saw-tooth signal S_{w1}′ and the first input voltage V_{rosc1} for comparing the first saw-tooth signal S_{w1}′ and the first input voltage V_{rosc1} to generate the reference signal V_{ref}. The first saw-tooth waveform generator 2011 comprises a single-pulse generating circuit 2011a, a first capacitor C₁′, a first current source I₁′, a first switch W₁′, a second switch W₂′, and a switch control circuit 2011b. The single-pulse generating circuit 2011a is coupled to the first signal S₁ for generating a one pulse signal Sₚ₁ in each cycle of the first signal S₁. The first capacitor C₁′ is coupled between an output node N₁′ of the first saw-tooth waveform generator 2011 and a first reference voltage Vₛₛ(i.e. a ground voltage). The first current source I₁′ is coupled to a second reference voltage V_{dd} (i.e. a supply voltage). The first switch W₁′ is coupled between the first current source I₁′ and the output node N₁′ of the first saw-tooth waveform generator 2011 for selectively coupling the first current source I₁′ to the first capacitor C₁′ according to a first switch control signal S_{c1}′. The second switch W₂′ is coupled between the output node N₁′ of the first saw-tooth waveform generator 2011 and the first reference voltage V_{dd} for selectively coupling the capacitor C₁′ to the first reference voltage V_{dd} according to a second switch control signal S_{c2}′. The switch control circuit 2011b is coupled to the single-pulse generating circuit 2011a, the first switch W₁′, and the second switch W₂′ for generating the first switch control signal S_{c1}′ and the second switch control signal S_{c2}′ according to an output (i.e. Sₚ₁) of the first single-pulse generating circuit 2011a.

The frequency generator 202 comprises a second saw-tooth waveform generator 2021 and a second comparator 2022. The second saw-tooth waveform generator 2021 is coupled to the second signal S2 for converting the second signal S₂ into a second saw-tooth signal S_{w2}′; and the second comparator 2022 is coupled to the second saw-tooth signal S_{w2}′ and the second input voltage V_{rosc2} for comparing the second saw-tooth signal S_{w2}′ and the second input voltage V_{rosc2} to generate the second signal S₂. The second saw-tooth waveform generator 2021 comprises a second capacitor C₂′, a second current source I₂′, a third switch W₃′, a fourth switch W₄′, and a switch control circuit 2021a. The second capacitor C₂′ is coupled between an output node N₂′ of the second saw-tooth waveform generator 2021 and the first reference voltage Vₛₛ. The second current source I₂′ is coupled to the second reference voltage V_{dd}. The third switch W₃′ is coupled between the second current source I₂′ and the output node N₂′ of the second saw-tooth waveform generator 2021, for selectively coupling the second current source to the second capacitor according to a third switch control signal S_{c3}′. The fourth switch W₄′ is coupled between the output node N₂′ of the second saw-tooth waveform generator 2021 and the first reference voltage Vₛₛ for selectively coupling the capacitor C₂′ to the first reference voltage Vₛₛ according to a fourth switch control signal S_{c4}′. The switch control circuit 2021a is coupled to the second signal S₂′, the third switch W₃′, and the fourth switch W₄′ for generating the third switch control signal S_{c3}′ and the fourth switch control signal S_{c4}′ according to the second signal S₂′ outputted from the output node N₂′ of the second saw-tooth waveform generator 2021.

Furthermore, in this embodiment, the adjusting circuit 204 is implemented by a voltage divider that comprises two resistors R₁ and R₂, wherein the resistors R₁ and R₂ are connected in series. An input node N₃′ of the adjusting circuit 204 is coupled to the first comparator 2012, and an output node N₄′ of the voltage divider 204 is coupled to the second comparator 2022. Please note that, compared to the frequency comparator 100, the frequency synthesizer 200 has an extra adjusting circuit 204 and replaces the decision logic 104 by the low-pass filter 205. On the other hand, the operation and the configuration of the frequency detecting circuit 201, the frequency generator 202, and the charge pump circuit 203 of the frequency synthesizer 200 are similar to the frequency detecting circuit 101, the frequency generator 102, the charge pump circuit 103 of the frequency comparator 100, therefore a detailed description is omitted here for brevity.

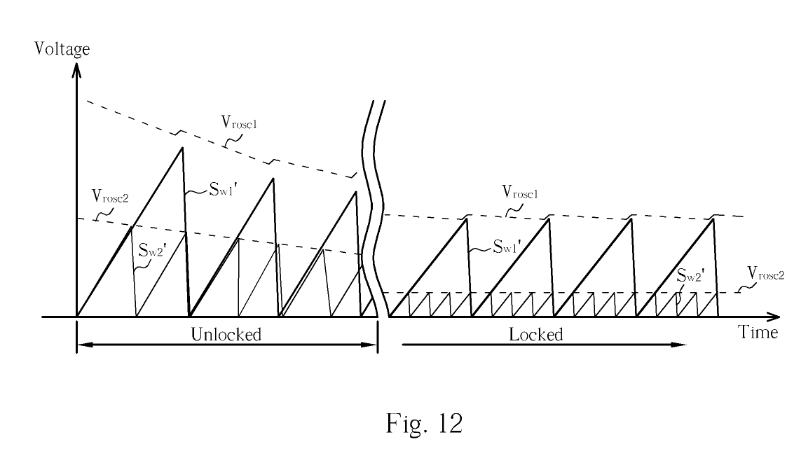

Please refer to the frequency synthesizer 200 in FIG. 11 again. The first current source I₁′ is the same as the second current source I₂′; the first capacitor C₁′ is the same as the second capacitor C₂′; and the charging current I_{c}′ is the same as the discharging current I_{dc}′. Furthermore, the input node N₃′ is coupled to the inverting terminal (i.e. N−) of the first comparator 2012 and the input node N₄′ is coupled to the inverting terminal (i.e. N−) of the second comparator 2022. Therefore, the ratio between the resistance of the resistors R₁ and R₂ decides the reference voltage of the second comparator 2022, i.e. the second input voltage V_{rosc2}. According to the above-mentioned disclosure, the first input voltage V_{rosc1} decides the turn on time of the switch W₅′ of the charge pump circuit 203 in each cycle of the first signal S₁ if the frequency of the first signal S₁(i.e. an external clock signal) is kept unchanged. For brevity, the ratio of the resistors R₁ and R₂ is set to 3, i.e. R₁/R₂=3. It should be noted that the ratio of the resistors R₁ and R₂ is allowed to be modified according to different design requirements. According to the frequency synthesizer 200 in FIG. 11, the resistor R₁, the first comparator 2012, the charge pump circuit 203, and the low-pass filter 205 form a closed loop feedback system. Therefore, the first input voltage V_{rosc1} will be locked at the peak voltage of the first saw-tooth signal S_{w1}′ as shown in FIG. 12. FIG. 12 is a timing diagram of the first input voltage V_{rosc1} the first saw-tooth signal S_{w1}′, and the second saw-tooth signal S_{w2}′. The second input voltage V_{rosc2} is one quarter of the first input voltage V_{rosc1} therefore the frequency generator 202 generates the second saw-tooth signal S_{w2}′ with a frequency four times (i.e. 1+R₁/R₂) as great as that of the first saw-tooth signal S_{w1}′ shown in FIG. 12. Accordingly, the second signal S₂ with a frequency four times as great as that of the first signal S₁ can be obtained by setting R₁/R₂=3. Similarly, any ratio of the resistors R₁ and R₂ can be set to obtain the required frequency of the second signal S₂. Following the same concept, a person skilled in this art could readily appreciate that the frequency synthesizer 200 can be configured to act as a frequency multiplier or a frequency divider with adequate connection between the voltage divider and the comparators 2012, 2022, where the frequency relation between the first signal S₁ and the second signal S₂ is set according to the resistors of the voltage divider.

Please note that the present invention is not limited to setting the ratio of the resistors R₁ and R₂, and any other method that is able to adjust the charging slope of the first saw-tooth signal S_{w1}′ and the second saw-tooth signal S_{w2}′ are within the scope of the present invention. For example, one of the embodiments of the present invention utilizes the first input voltage V_{rosc1} to set the first current source I₁′ and the second current source I₂′ for locking the required frequency; and another embodiment of the present invention utilizes the first input voltage V_{rosc1} to set the first capacitor C₁′ and the second capacitor C₂′ for locking the required frequency. Furthermore, those skilled in this art can readily understand that utilizing the first input voltage V_{rosc1} to adjust the resistors R₁ and R₂, the first current source I₁′ and the second current source I₂′, the first capacitor C₁′ and the second capacitor C₂′, or any combination thereof can achieve the same goal of controlling the frequency relation between the first signal S₁ and the second signal S₂. These all obey the spirit of the present invention.

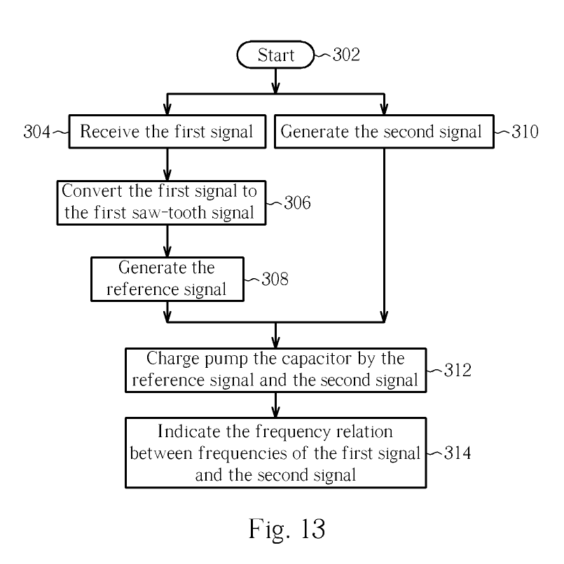

Please refer to FIG. 13. FIG. 13 is a flow chart illustrating a frequency comparing method according to an embodiment of the present invention. The frequency comparing method compares the frequencies of the first signal S₁ and the second signal S₂ of the embodiment in FIG. 2. The frequency comparing method is briefly described by the following steps:

Step 302: Start;

Step 304: Receive the first signal S₁;

Step 306: Convert the first signal S₁ to the first saw-tooth signal S_{w1};

Step 308: Compare the first saw-tooth signal S_{w1} with the input voltage V_{rosc} to generate the reference signal V_{ref}; go to step 312;

Step 310: Generate the second signal S₂ that corresponds to the input voltage V_{rosc}; go to step 312;

Step 312: Charge pump the capacitor C₅ by the reference signal V_{ref} and the second signal S₂;

Step 314: Utilize the decision logic 104 to indicate the frequency relation between frequencies of the first signal S₁ and the second signal S₂.

Please note that the steps 302˜314 of the frequency comparing method have been described by the embodiment of the frequency comparator 100, and therefore the detailed description is omitted here for brevity.

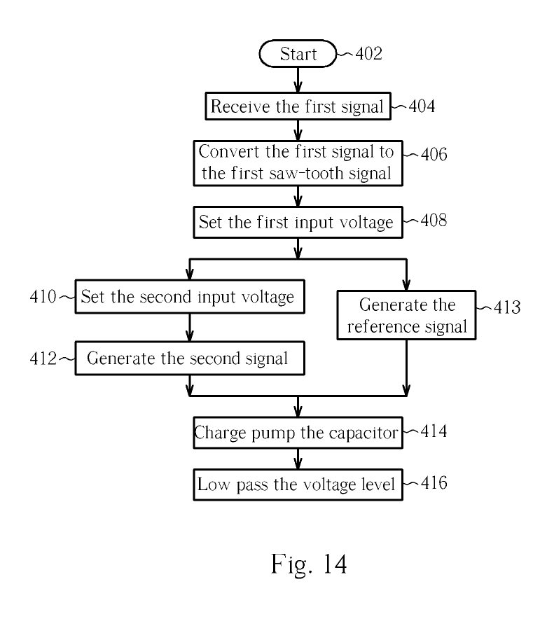

Please refer to FIG. 14. FIG. 14 is a flow chart illustrating a frequency synthesizing method according to an embodiment of the present invention. The frequency synthesizing method generates the frequencies of the second signal S₂ according to the first signal S₁ of the embodiment in FIG. 11. The frequency synthesizing method is briefly described by the following steps:

Step 402: Start;

Step 404: Receive the first signal S₁;

Step 406: Convert the first signal S₁ to the first saw-tooth signal S_{w1}′;

Step 408: Set the first input voltage V_{rosc1}; go to step 413;

Step 410: Set the second input voltage V_{rosc2};

Step 412: Generate the second signal S₂; go to step 414;

Step 413: Generate the reference signal S_{ref};

Step 414: Charge pump the capacitor C₅′ by the reference signal S_{ref} and the second signal S₂;

Step 416: Low pass the voltage level Vₒₛₑₜ to generate the first input voltage V_{rosc1}; go to step 408.

Please note that the steps 402˜416 of the frequency synthesizing method have been described by the embodiment of the frequency synthesizer 200, and therefore the detailed description is omitted here for brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A frequency comparator, for comparing frequencies of a first signal and a second signal, comprising:
a frequency detecting circuit, for generating a reference signal according to the first signal and an input voltage;
a frequency generator, for generating the second signal according to the input voltage;
a charge pump circuit, coupled to the frequency detecting circuit and the frequency generator, for enabling a charging current according to one of the reference signal and the second signal to increase an voltage level, and for enabling a discharging current according to the other of the reference signal and the second signal to decrease the voltage level; and
a decision logic, coupled to the charge pump circuit, for indicating a frequency relation between frequencies of the first signal and the second signal according to the voltage level.

2. The frequency comparator of claim 1, wherein the frequency detecting circuit comprises:
a first saw-tooth waveform generator, coupled to the first signal, for converting the first signal into a first saw-tooth signal; and
a first comparator, coupled to the first saw-tooth signal and the input voltage, for comparing the first saw-tooth signal and the input voltage to generate the reference signal.

3. The frequency comparator of claim 2, wherein the first saw-tooth waveform generator comprises:
a single-pulse generating circuit, coupled to the first signal, for generating a one pulse signal in each cycle of the first signal;
a first capacitor, coupled between an output node of the first saw-tooth waveform generator and a first reference voltage;
a first current source, coupled to a second reference voltage;
a first switch, coupled between the first current source and the output node of the first saw-tooth waveform generator, for selectively coupling the first current source to the first capacitor according to a first switch control signal;
a second switch, coupled between the output node of the first saw-tooth waveform generator and the first reference voltage, for selectively coupling the first capacitor to the first reference voltage according to a second switch control signal; and
a switch control circuit, coupled to the single-pulse generating circuit, the first switch, and the second switch, for generating the first switch control signal and the second switch control signal according to an output of the first single-pulse generating circuit.

4. The frequency comparator of claim 1, wherein the frequency generator comprises:
a second saw-tooth waveform generator, coupled to the second signal, for converting the second signal into a second saw-tooth signal; and
a second comparator, coupled to the second saw-tooth signal and the input voltage, for comparing the second saw-tooth signal and the input voltage to generate the second signal.

5. The frequency comparator of claim 4, wherein the second saw-tooth waveform generator comprises:
a second capacitor, coupled between an output node of the second saw-tooth waveform generator and a first reference voltage;
a second current source, coupled to a second reference voltage;
a third switch, coupled between the second current source and the output node of the second saw-tooth waveform generator, for selectively coupling the second current source to the second capacitor according to a third switch control signal;
a fourth switch, coupled between the output node of the second saw-tooth waveform generator and the first reference voltage, for selectively coupling the capacitor to the first reference voltage according to a fourth switch control signal; and
a switch control circuit, coupled to the second signal, the third switch, and the fourth switch, for generating the third switch control signal and the fourth switch control signal according to the second signal outputted from the output node of the second saw-tooth waveform generator.

6. The frequency comparator of claim 1, wherein the decision logic comprises the voltage level and a third reference voltage to output an indication signal indicating the frequency relation between frequencies of the first signal and the second signal.

7. The frequency comparator of claim 1, further comprising:
a resistor; and
a reference voltage generating circuit, coupled to the resistor, for setting the input voltage according to a resistance of the resistor;
wherein the reference voltage generating circuit, the frequency detecting circuit, the frequency generator, the charge pump circuit, and the decision logic are all integrated in a chip, and the resistor is external to the chip.

8. A frequency synthesizer, for generating a second signal according to a first signal, comprising:
a frequency detecting circuit, for generating a reference signal according to the first signal and a first input voltage;
a frequency generator, for generating the second signal according to a second input voltage;
a charge pump circuit, coupled to the frequency detecting circuit and the frequency generator, for enabling a charging current according to one of the reference signal and the second signal to increase an voltage level, and for enabling a discharging current according to the other of the reference signal and the second signal to decrease the voltage level; and
an adjusting circuit, coupled to the charge pump circuit, the frequency detecting circuit, and the frequency generator, for adjusting the frequency detecting circuit and the frequency generator according to the voltage level to thereby tune frequencies of the reference signal and the second signal.

9. The frequency synthesizer of claim 8, further comprising:
a low-pass filter, coupled between the charge pump circuit and the adjusting circuit, for low-pass filtering the voltage level outputted to the adjusting circuit.

10. The frequency synthesizer of claim 8, wherein the frequency detecting circuit comprises:
a first saw-tooth waveform generator, coupled to the first signal, for converting the first signal into a first saw-tooth signal; and
a first comparator, coupled to the first saw-tooth signal and the first input voltage, for comparing the first saw-tooth signal and the first input voltage to generate the reference signal.

11. The frequency synthesizer of claim 10, wherein the first saw-tooth waveform generator comprises:
a single-pulse generating circuit, coupled to the first signal, for generating a one pulse signal in each cycle of the first signal;
a first capacitor, coupled between an output node of the first saw-tooth waveform generator and a first reference voltage;
a first current source, coupled to a second reference voltage;
a first switch, coupled between the first current source and the output node of the first saw-tooth waveform generator, for selectively coupling the first current source to the first capacitor according to a first switch control signal;
a second switch, coupled between the output node of the first saw-tooth waveform generator and the first reference voltage, for selectively coupling the first capacitor to the first reference voltage according to a second switch control signal; and
a switch control circuit, coupled to the single-pulse generating circuit, the first switch, and the second switch, for generating the first switch control signal and the second switch control signal according to an output of the first single-pulse generating circuit.

12. The frequency synthesizer of claim 11, wherein the frequency generator comprises:
a second saw-tooth waveform generator, coupled to the second signal, for converting the second signal into a second saw-tooth signal; and
a second comparator, coupled to the second saw-tooth signal and the second input voltage, for comparing the second saw-tooth signal and the second input voltage to generate the second signal.

13. The frequency synthesizer of claim 12, wherein the second saw-tooth waveform generator comprises:
a second capacitor, coupled between an output node of the second saw-tooth waveform generator and the first reference voltage;
a second current source, coupled to the second reference voltage;
a third switch, coupled between the second current source and the output node of the second saw-tooth waveform generator, for selectively coupling the second current source to the second capacitor according to a third switch control signal;
a fourth switch, coupled between the output node of the second saw-tooth waveform generator and the first reference voltage, for selectively coupling the capacitor to the first reference voltage according to a fourth switch control signal; and
a switch control circuit, coupled to the second signal, the third switch, and the fourth switch, for generating the third switch control signal and the fourth switch control signal according to the second signal outputted from the output node of the second saw-tooth waveform generator.

14. The frequency synthesizer of claim 13, wherein the first input voltage is different from the second input voltage, and the adjusting circuit adjusts the first input voltage and the second input voltage according to the voltage level outputted from the charge pump circuit.

15. The frequency synthesizer of claim 14, wherein the adjusting circuit is a voltage divider, an input node of the voltage divider is coupled to one of the first comparator and the second comparator, and an output node of the voltage divider is coupled to the other of the first comparator and the second comparator.

16. The frequency synthesizer of claim 15, wherein the voltage divider comprises a plurality of resistors; the frequency detecting circuit, the frequency generator, and the charge pump circuit are all integrated in a chip; and at least one of the resistors of the adjusting circuit is external to the chip.

17. The frequency synthesizer of claim 13, wherein the first input voltage is equal to the second input voltage, and the adjusting circuit adjusts the first current source and the second current source according to the voltage level outputted from the charge pump circuit.

18. The frequency synthesizer of claim 13, wherein the first input voltage is equal to the second input voltage, and the adjusting circuit adjusts the first capacitor and the second capacitor according to the voltage level outputted from the charge pump circuit.

19. The frequency synthesizer of claim 8, wherein the frequency generator comprises:
a second saw-tooth waveform generator, coupled to the second signal, for converting the second signal into a second saw-tooth signal; and
a second comparator, coupled to the second saw-tooth signal and the second input voltage, for comparing the second saw-tooth signal and the second input voltage to generate the reference signal.

20. The frequency synthesizer of claim 19, wherein the second saw-tooth waveform generator comprises:
a second capacitor, coupled between an output node of the second saw-tooth waveform generator and a first reference voltage;
a second current source, coupled to a second reference voltage;
a third switch, coupled between the second current source and the output node of the first saw-tooth waveform generator, for selectively coupling the second current source to the second capacitor according to a third switch control signal;
a fourth switch, coupled between the output node of the second saw-tooth waveform generator and the first reference voltage, for selectively coupling the capacitor to the first reference voltage according to a fourth switch control signal; and
a switch control circuit, coupled to the second signal, the third switch, and the fourth switch, for generating the third switch control signal and the fourth switch control signal according to the second signal outputted from the output node of the second saw-tooth waveform generator.

21. A frequency comparing method, for comparing frequencies of a first signal and a second signal, comprising:
(a) generating a reference signal according to the first signal and an input voltage;
(b) generating the second signal according to the input voltage;
(c) enabling a charging current according to one of the reference signal and the second signal to increase a voltage level, and for enabling a discharging current according to the other of the reference signal and the second signal to decrease the voltage level; and
(d) indicating a frequency relation between frequencies of the first signal and the second signal according to the voltage level.

22. The frequency comparing method of claim 21, wherein the step (a) comprises:
converting the first signal into a first saw-tooth signal; and
comparing the first saw-tooth signal and the input voltage to generate the reference signal.

23. The frequency comparing method of claim 22, wherein the step of converting the first signal into the first saw-tooth signal comprises:
generating one pulse signal in each cycle of the first signal;
providing a first capacitor;
providing a first current source;
selectively coupling the first current source to the first capacitor according to a first switch control signal;
selectively coupling the first capacitor to the first reference voltage according to a second switch control signal; and
generating the first switch control signal and the second switch control signal according to the one pulse signal in each cycle of the first signal.

24. The frequency comparing method of claim 21, wherein the step (b) comprises:
converting the second signal into a second saw-tooth signal; and
comparing the second saw-tooth signal and the input voltage to generate the second signal.

25. The frequency comparing method of claim 24, wherein the step of converting the second signal into the second saw-tooth signal comprises:
providing a second capacitor;
providing a second current source;
selectively coupling the second current source to the second capacitor according to a third switch control signal;
selectively coupling the capacitor to the first reference voltage according to a fourth switch control signal; and
generating the third switch control signal and the fourth switch control signal according to the second signal.

26. The frequency comparing method of claim 21, wherein the step (d) comprises outputting an indication signal to indicate the frequency relation between frequencies of the first signal and the second signal according to the voltage level and a third reference voltage.

27. The frequency comparing method of claim 21, further comprising:
providing a resistor; and
setting the input voltage according to a resistance of the resistor.

28. A frequency synthesizing method, for generating a second signal according to a first signal, comprising:
(e) generating a reference signal according to the first signal and a first input voltage;
(f) generating the second signal according to a second input voltage;
(g) enabling a charging current according to one of the reference signal and the second signal to increase a voltage level, and for enabling a discharging current according to the other of the reference signal and the second signal to decrease the voltage level; and
(h) adjusting the frequency detecting circuit and the frequency generator according to the voltage level to thereby tune frequencies of the reference signal and the second signal.

29. The frequency synthesizing method of claim 28, further comprising:
low-pass filtering the voltage level.

30. The frequency synthesizing method of claim 28, wherein the step (e) comprises:
converting the first signal into a first saw-tooth signal; and
comparing the first saw-tooth signal and the first input voltage to generate the reference signal.

31. The frequency synthesizing method of claim 30, wherein the step of converting the first signal into the first saw-tooth signal comprises:
generating a one pulse signal in each cycle of the first signal;
providing a first capacitor;
providing a first current source;
selectively coupling the first current source to the first capacitor according to a first switch control signal;
selectively coupling the first capacitor to the first reference voltage according to a second switch control signal; and
generating the first switch control signal and the second switch control signal according to the one pulse signal in each cycle of the first signal.

32. The frequency synthesizing method of claim 31, wherein the step (f) comprises:
converting the second signal into a second saw-tooth signal; and
comparing the second saw-tooth signal and the second input voltage to generate the second signal.

33. The frequency synthesizing method of claim 32, wherein the step of converting the second signal into the second saw-tooth signal comprises:
providing a second capacitor;
providing a second current source;
selectively coupling the second current source to the second capacitor according to a third switch control signal;
selectively coupling the capacitor to the first reference voltage according to a fourth switch control signal; and
generating the third switch control signal and the fourth switch control signal according to the second signal.

34. The frequency synthesizing method of claim 33, wherein the first input voltage is different from the second input voltage, and the step (h) adjusts the first input voltage and the second input voltage according to the voltage level.

35. The frequency synthesizing method of claim 33, wherein the first input voltage is equal to the second input voltage, and the step (h) adjusts the first current source and the second current source according to the voltage level.

36. The frequency synthesizing method of claim 33, wherein the first input voltage is equal to the second input voltage, and the step (h) adjusts the first capacitor and the second capacitor according to the voltage level.

37. The frequency synthesizing method of claim 28, wherein the step (h) comprises:
converting the second signal into a second saw-tooth signal; and
comparing the second saw-tooth signal and the second input voltage to generate the reference signal.

38. The frequency synthesizing method of claim 37, wherein the step of converting the second signal into the second saw-tooth signal comprises:
providing a second capacitor;
providing a second current source;
selectively coupling the second current source to the second capacitor according to a third switch control signal;
selectively coupling the capacitor to the first reference voltage according to a fourth switch control signal; and
generating the third switch control signal and the fourth switch control signal according to the second signal.
